(19) United States
(12) Patent Application Publication
(10) Pub. No.: US 2026/0282409 A1
(43) Pub. Date: Sep. 17, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yoko IWAKAJI, Meguro Tokyo (JP); Kenichi MATSUSHITA, Nonoichi Ishikawa (JP); Takahiro KATO, Nonoichi Ishikawa (JP)

(21) Appl. No.: 19/250,061

(22) Filed: Jun. 26, 2025

(30) Foreign Application Priority Data
Mar. 11, 2025 (JP) 2025-038421

(51) Int. Cl. H10D 12/00; H10D 8/00; H10D 62/10; H10D 62/60

(52) U.S. Cl. CPC H10D 12/481; H10D 8/422; H10D 62/103; H10D 62/126; H10D 62/60

(57) ABSTRACT

A semiconductor part includes a first semiconductor layer, a second semiconductor layer positioned between a first electrode and the first semiconductor layer in the transistor region, a third semiconductor layer positioned between the first semiconductor layer and a second electrode in the transistor region, a fourth semiconductor layer positioned between the third semiconductor layer and the second electrode in the transistor region, a fifth semiconductor layer positioned between the first semiconductor layer and the third semiconductor layer in the transistor region, a sixth semiconductor layer positioned between the first electrode and the first semiconductor layer in the diode region, and a seventh semiconductor layer positioned between the first semiconductor layer and the second electrode in the diode region. A first-conductivity-type impurity concentration of the fifth semiconductor layer positioned in a second region is greater than a first-conductivity-type impurity concentration of the fifth semiconductor layer positioned in a first region.

### CROSS-REFERENCE TO RELATED APPLICATION

This application is based upon and claims the benefit of priority from Japanese Patent Application No. 2025-038421, filed on Mar. 11, 2025; the entire contents of which are incorporated herein by reference.

### FIELD

Embodiments described herein relate generally to a semiconductor device.

### BACKGROUND

IGBTs (Insulated Gate Bipolar Transistors) are widely used as semiconductor devices for power control. In many applications using IGBTs, there is a mode in which a return current flows from the emitter side to the collector side; and a FWD (Free-Wheeling Diode) is connected in anti-parallel to the IGBT to carry the return current. A reverse-conducting IGBT (RC-IGBT) is a semiconductor device in which the FWD is embedded inside the IGBT chip.

### BRIEF DESCRIPTION OF THE DRAWINGS

FIG. 1 is a schematic cross-sectional view of a semiconductor device of a first embodiment;

FIG. 2 is a schematic plan view of a semiconductor part of an embodiment;

FIG. 3 is a schematic cross-sectional view of a semiconductor device of a second embodiment;

FIG. 4 is a schematic cross-sectional view of a semiconductor device of a third embodiment; and

FIGS. 5 and 6 are schematic plan views showing arrangement examples of a third electrode and a fourth semiconductor layer in embodiments.

### DETAILED DESCRIPTION

According to one embodiment, a semiconductor device includes a first electrode; a second electrode; a semiconductor part positioned between the first electrode and the second electrode in a first direction, the semiconductor part including a transistor region, and a diode region adjacent to the transistor region in a direction crossing the first direction; and a third electrode positioned in the semiconductor part, the semiconductor part including a first semiconductor layer positioned in the transistor region and the diode region, the first semiconductor layer being of a first conductivity type, a second semiconductor layer positioned between the first electrode and the first semiconductor layer in the transistor region, the second semiconductor layer being of a second conductivity type, a third semiconductor layer positioned between the first semiconductor layer and the second electrode in the transistor region, the third semiconductor layer being of the second conductivity type and being electrically connected with the second electrode, a fourth semiconductor layer positioned between the third semiconductor layer and the second electrode in the transistor region, the fourth semiconductor layer being of the first conductivity type and being electrically connected with the second electrode, a fifth semiconductor layer positioned between the first semiconductor layer and the third semiconductor layer in the transistor region, the fifth semiconductor layer being of the first conductivity type and having a higher first-conductivity-type impurity concentration than the first semiconductor layer, a sixth semiconductor layer positioned between the first electrode and the first semiconductor layer in the diode region, the sixth semiconductor layer being of the first conductivity type and having a higher first-conductivity-type impurity concentration than the first semiconductor layer, and a seventh semiconductor layer positioned between the first semiconductor layer and the second electrode in the diode region, the seventh semiconductor layer being of the second conductivity type and being electrically connected with the second electrode, the transistor region including a first region, and a second region positioned between the first region and the diode region in the direction crossing the first direction, a first-conductivity-type impurity concentration of the fifth semiconductor layer positioned in the second region being greater than a first-conductivity-type impurity concentration of the fifth semiconductor layer positioned in the first region.

Exemplary embodiments will now be described with reference to the drawings. Similar components in the drawings are marked with like reference numerals. In the drawings, a direction along a Z-axis is referred to as a first direction Z; a direction along an X-axis is referred to as a second direction X; and a direction along a Y-axis is referred to as a third direction Y. The second direction X and the third direction Y are directions that cross the first direction Z. According to the embodiment, for example, the first direction Z, the second direction X, and the third direction Y are orthogonal to each other. In the description of the specification, for example, the arrow direction of the Z-axis may be referred to as relatively up or above; and the opposite direction of the arrow of the Z-axis may be referred to as relatively down or below.

In the specification, the thickness of each component represents the maximum value of the thickness in the first direction Z. In the specification, the distance in a specific direction between components represents the shortest distance in the specific direction.

### First Embodiment

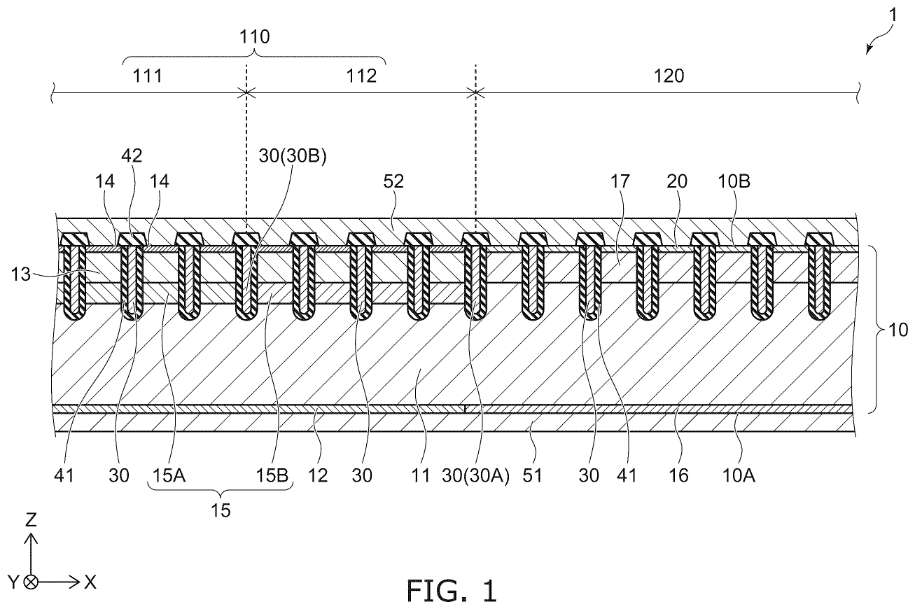

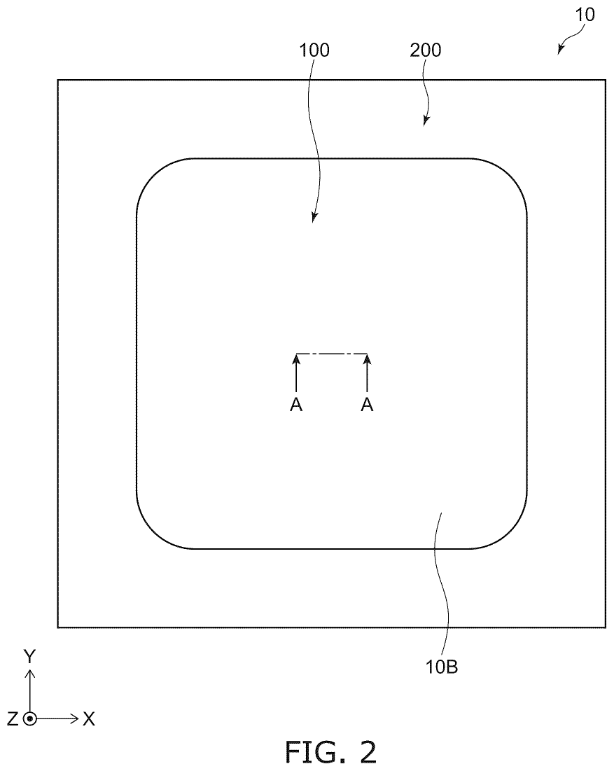

A semiconductor device 1 according to a first embodiment will now be described with reference to FIGS. 1 and 2.

As shown in FIG. 1, the semiconductor device 1 includes a first electrode 51, a second electrode 52, a third electrode 30, an insulating film 41, an insulating layer 42, and a semiconductor part 10.

The semiconductor part 10 is positioned between the first electrode 51 and the second electrode 52 in the first direction Z. The semiconductor part 10 includes a first surface 10A, and a second surface 10B positioned at the side opposite to the first surface 10A in the first direction Z. The first electrode 51 is located at the first surface 10A. The second electrode 52 is positioned above the second surface 10B.

FIG. 2 is a schematic plan view of the second surface 10B of the semiconductor part 10. The cross section of the semiconductor part 10 shown in FIG. 1 corresponds to an A-A cross section of FIG. 2.

The semiconductor part 10 includes an element region 100 and a termination region 200. The termination region 200 is positioned between the element region 100 and the outer edge of the semiconductor part 10 in the second and third directions X and Y. The termination region 200 surrounds the element region 100 when viewed in plan.

For example, silicon can be used as the material of the semiconductor part 10. Or, for example, silicon carbide, gallium nitride, etc., may be used as the material of the semiconductor part 10. Although a first conductivity type is described as an n-type and a second conductivity type is described as a p-type in the semiconductor part 10 according to the embodiment, the first conductivity type may be the p-type; and the second conductivity type may be the n-type.

The semiconductor part 10 includes a transistor region 110 and a diode region 120. According to the embodiment, the diode region 120 is adjacent to the transistor region 110 in the second direction X. The transistor region 110 and the diode region 120 are included in the element region 100. In the element region 100, for example, the transistor region 110 and the diode region 120 are alternately arranged in the second direction X.

The semiconductor part 10 includes an n-type first semiconductor layer 11, a p-type second semiconductor layer 12, a p-type third semiconductor layer 13, an n-type fourth semiconductor layer 14, an n-type fifth semiconductor layer 15, an n-type sixth semiconductor layer 16, a p-type seventh semiconductor layer 17, and a p-type tenth semiconductor layer 20.

The transistor region 110 includes an IGBT. In the IGBT of the transistor region 110, the first electrode 51 functions as a collector electrode; the second electrode 52 functions as an emitter electrode; the first semiconductor layer 11 functions as an n-type base layer (or drift layer); the second semiconductor layer 12 functions as a p-type collector layer; the third semiconductor layer 13 functions as a p-type base layer; the fourth semiconductor layer 14 functions as an n-type emitter layer; and the fifth semiconductor layer 15 functions as an n-type barrier layer.

The first semiconductor layer 11 (the n-type base layer) is continuous in the transistor region 110 and the diode region 120.

The second semiconductor layer 12 (the p-type collector layer) is positioned between the first electrode 51 and the first semiconductor layer 11 in the transistor region 110. The second semiconductor layer 12 contacts the first electrode 51 and is electrically connected with the first electrode 51.

The third semiconductor layer 13 (the p-type base layer) is positioned between the first semiconductor layer 11 and the second electrode 52 in the transistor region 110 and is electrically connected with the second electrode 52. The p-type impurity concentration of the second semiconductor layer 12 is greater than the p-type impurity concentration of the third semiconductor layer 13.

The fourth semiconductor layer 14 (the n-type emitter layer) is positioned between the third semiconductor layer 13 and the second electrode 52 in the transistor region 110. The n-type impurity concentration of the fourth semiconductor layer 14 is greater than the n-type impurity concentration of the first semiconductor layer 11. The fourth semiconductor layer 14 is electrically connected with the second electrode 52. The second electrode 52 contacts the front surface of the fourth semiconductor layer 14. The second electrode 52 may have a trench contact structure contacting the side surface of the fourth semiconductor layer 14.

The fifth semiconductor layer 15 (the n-type barrier layer) is positioned between the first semiconductor layer 11 and the third semiconductor layer 13 in the transistor region 110. The n-type impurity concentration of the fifth semiconductor layer 15 is greater than the n-type impurity concentration of the first semiconductor layer 11.

The transistor region 110 includes a first region 111 and a second region 112. The second region 112 is positioned between the first region 111 and the diode region 120 in the second direction X. The first region 111, the second region 112, and the diode region 120 are repeated in the second direction X inside the element region 100.

The fifth semiconductor layer 15 includes a first part 15A positioned in the first region 111, and a second part 15B positioned in the second region 112. The n-type impurity concentration of the second part 15B of the fifth semiconductor layer 15 positioned in the second region 112 is greater than the n-type impurity concentration of the first part 15A of the fifth semiconductor layer 15 positioned in the first region 111. When the n-type impurity concentration of the second part 15B of the fifth semiconductor layer 15 positioned in at least a part of the second region 112 is greater than the n-type impurity concentration of the first part 15A of the fifth semiconductor layer 15 positioned in the first region 111, the recovery loss (the switching loss) during reverse recovery of a diode operation described below can be reduced. In other words, it is unnecessary to compare the n-type impurity concentration of the second part 15B of the fifth semiconductor layer 15 positioned in the second region 112 and the n-type impurity concentration of the first part 15A of the fifth semiconductor layer 15 positioned in the first region 111 over the entire region. On the other hand, it is desirable for the n-type impurity concentration of the second part 15B of the fifth semiconductor layer 15 positioned in the second region 112 to be greater, over the entire surface of the second region 112, than the n-type impurity concentration of the first part 15A of the fifth semiconductor layer 15 positioned in the first region 111. The switching loss of the diode operation described below can be further reduced.

The diode region 120 includes a diode that is connected in anti-parallel with the IGBT of the transistor region 110. In the diode of the diode region 120, the first electrode 51 functions as a cathode electrode; the second electrode 52 functions as an anode electrode; the sixth semiconductor layer 16 functions as an n-type cathode layer; and the seventh semiconductor layer 17 functions as a p-type anode layer.

The sixth semiconductor layer 16 (the n-type cathode layer) is positioned between the first electrode 51 and the first semiconductor layer 11 in the diode region 120. The n-type impurity concentration of the sixth semiconductor layer 16 is greater than the n-type impurity concentration of the first semiconductor layer 11. The sixth semiconductor layer 16 (the n-type cathode layer) is adjacent to the second semiconductor layer 12 (the p-type collector layer) in the second direction X.

The seventh semiconductor layer 17 (the p-type anode layer) is positioned between the first semiconductor layer 11 and the second electrode 52 in the diode region 120 and is electrically connected with the second electrode 52. The seventh semiconductor layer 17 contacts the first semiconductor layer 11 in the first direction Z and has a p-n junction with the first semiconductor layer 11.

The tenth semiconductor layer 20 is formed at, at least, a portion of the front surface of the seventh semiconductor layer 17. The p-type impurity concentration of the tenth semiconductor layer 20 is greater than the p-type impurity concentration of the seventh semiconductor layer 17. The second electrode 52 contacts the tenth semiconductor layer 20. The seventh semiconductor layer 17 is electrically connected with the second electrode 52 via the tenth semiconductor layer 20.

The fourth semiconductor layer 14 (the n-type emitter layer) is not included in the diode region 120. According to the first embodiment, the fifth semiconductor layer 15 (the n-type barrier layer) is not included in the diode region 120.

The third electrode 30 extends downward from the second surface 10B of the semiconductor part 10 and is positioned inside the semiconductor part 10. In the transistor region 110, the lower end of the third electrode 30 is positioned inside the first semiconductor layer 11 (the n-type base layer) and is lower than the p-n junction between the third semiconductor layer 13 (the p-type base layer) and the fifth semiconductor layer 15 (the n-type barrier layer). The lower end of the third electrode 30 is positioned lower than the interface between the fifth semiconductor layer 15 (the n-type barrier layer) and the first semiconductor layer 11 (the n-type base layer). For example, conductive polycrystalline silicon can be used as the material of the third electrode 30.

The insulating film 41 is located between the third electrode 30 and the semiconductor part 10. In the transistor region 110, the side surface of the third electrode 30 faces the third semiconductor layer 13 (the p-type base layer) via the insulating film 41. The insulating layer 42 is located between the third electrode 30 and the second electrode 52. In the transistor region 110, the lower end of the insulating film 41 is positioned inside the first semiconductor layer 11 (the n-type base layer) and is lower than the p-n junction between the third semiconductor layer 13 (the p-type base layer) and the fifth semiconductor layer 15 (the n-type barrier layer). The lower end of the insulating film 41 is positioned lower than the interface between the fifth semiconductor layer 15 (the n-type barrier layer) and the first semiconductor layer 11 (the n-type base layer).

Multiple third electrodes 30 are located in the transistor region 110 and the diode region 120. The multiple third electrodes 30 are separated from each other in the second direction X; and each third electrode 30 extends in the third direction Y.

The multiple third electrodes 30 include a third electrode 30A positioned at the boundary between the transistor region 110 and the diode region 120. One side surface of the two side surfaces in the second direction X of the third electrode 30A positioned at the transistor region 110 side is adjacent to the third semiconductor layer 13 (the p-type base layer) and the fifth semiconductor layer 15 (the n-type barrier layer) with the insulating film 41 interposed. The other side surface of the two side surfaces of the third electrode 30A positioned at the diode region 120 side is adjacent to the seventh semiconductor layer 17 (the p-type anode layer) with the insulating film 41 interposed.

The multiple third electrodes 30 also include a third electrode 30B positioned at the boundary between the first region 111 and the second region 112. One side surface of the two side surfaces in the second direction X of the third electrode 30B positioned at the first region 111 side is adjacent to the first part 15A of the fifth semiconductor layer 15 with the insulating film 41 interposed. The other side surface of the two side surfaces of the third electrode 30B positioned at the second region 112 side is adjacent to the second part 15B of the fifth semiconductor layer 15 with the insulating film 41 interposed.

The boundary between the second semiconductor layer 12 (the p-type collector layer) and the sixth semiconductor layer 16 (the n-type cathode layer) may or may not match the boundary between the transistor region 110 and the diode region 120 (the position of the third electrode 30A). The boundary between the second semiconductor layer 12 (the p-type collector layer) and the sixth semiconductor layer 16 (the n-type cathode layer) may be positioned at the transistor region 110 side or the diode region 120 side.

The third electrode 30 that is located in the transistor region 110 functions as a trench gate electrode of the IGBT and is connected with a gate wiring part (not illustrated). For example, the end of the third electrode 30 (the gate electrode) extending in the third direction Y from the transistor region 110 to the termination region 200 is connected with the gate wiring part in the termination region 200. The third electrode 30 (the gate electrode) may be connected with the gate wiring part in the element region 100.

The third electrode 30 that is located in the diode region 120 is not connected to a gate wiring part and is connected with, for example, the second electrode 52. For example, the end of the third electrode 30 extending in the third direction Y from the diode region 120 to the termination region 200 is connected with the second electrode 52 in the termination region 200. The third electrode 30 may be connected with the second electrode 52 in the element region 100. The third electrode 30 that is located in the diode region 120 does not function as a gate electrode of a transistor. By forming dummy trench electrodes in the diode region 120, fluctuation of the shapes and/or dimensions of the trenches and the third electrodes 30 (the gate electrodes) formed in the transistor region 110 can be reduced, and fluctuation of the breakdown voltage in the transistor region 110 and the diode region 120 can be reduced.

In the IGBT operation of the transistor region 110, a positive potential is applied to the first electrode 51 (the collector electrode); and a ground potential is applied to the second electrode 52 (the emitter electrode). When a potential that is greater than a prescribed threshold (a potential that is higher than the potential of the second electrode 52 (the emitter electrode)) is applied to the third electrode 30 (the gate electrode) of the transistor region 110, an inversion layer (an n-type channel) is formed in the region of the third semiconductor layer 13 (the p-type base layer) facing the third electrode 30; and electrons are injected from the second electrode 52 into the first semiconductor layer 11 (the n-type base layer) via the fourth semiconductor layer 14 (the n-type emitter layer), the n-type channel, and the fifth semiconductor layer 15. Therefore, the second semiconductor layer 12 (the p-type collector layer) is biased to be positive with respect to the first semiconductor layer 11; holes are injected from the second semiconductor layer 12 into the first semiconductor layer 11; and the IGBT of the transistor region 110 is switched to an on-state. When a potential that is less than the threshold is applied to the third electrode 30 (the gate electrode) of the transistor region 110, the n-type channel disappears, and the IGBT is switched to an off-state.

In the IGBT operation of the transistor region 110, the fifth semiconductor layer 15 (the n-type barrier layer) makes it difficult for the holes injected into the first semiconductor layer 11 (the n-type base layer) to be discharged into the second electrode 52 via the third semiconductor layer 13 (the p-type base layer), and makes it easy for holes to accumulate in the first semiconductor layer 11. The on-resistance of the IGBT can be reduced thereby. On the other hand, if too many holes accumulate in the first semiconductor layer 11, there is a risk that more carriers may be discharged when the IGBT is turned off, and the turn-off loss of the IGBT operation may be increased. In other words, when including the fifth semiconductor layer 15, there may be a trade-off relationship between the on-resistance of the IGBT and the turn-off loss of the IGBT.

In the diode operation of the diode region 120, when a ground potential is applied to the first electrode 51 (the cathode electrode) and a positive potential is applied to the second electrode 52 (the anode electrode), holes are injected from the second electrode 52 into the first semiconductor layer 11 via the tenth and seventh semiconductor layers 20 and 17; electrons are injected from the first electrode 51 into the first semiconductor layer 11 via the sixth semiconductor layer 16; and a forward current flows in the diode of the diode region 120.

In the diode operation, holes may be injected from the third semiconductor layer 13 (the p-type base layer) of the transistor region 110 into the first semiconductor layer 11 of the diode region 120. Such an injection of holes may increase the switching loss of the diode. Compared to hole injection from the first region 111, holes are easily injected into the first semiconductor layer 11 of the diode region 120 from the second region 112 adjacent to the diode region 120 in the transistor region 110.

According to the embodiment, in the fifth semiconductor layer 15 (the n-type barrier layer) positioned in the transistor region 110, the n-type impurity concentration of the second part 15B positioned in the second region 112 proximate to the diode region 120 is set to be greater than the n-type impurity concentration of the first part 15A positioned in the first region 111 more distant to the diode region 120 than the second region 112. As a result, in the diode operation, fewer holes can be injected from the third semiconductor layer 13 (the p-type base layer) of the transistor region 110 into the first semiconductor layer 11 of the diode region 120; and the switching loss of the diode operation can be reduced.

The n-type impurity concentration of the fifth semiconductor layer 15 is not set to be high over the entire region of the transistor region 110; the n-type impurity concentration is set to be high only in the second part 15B positioned in the second region 112 proximate to the diode region 120. As a result, the switching loss of the diode operation can be reduced while reducing the turn-off loss of the IGBT operation.

If the width in the second direction X of the second region 112 becomes large, there is a risk that the turn-off loss of the IGBT may be increased. Accordingly, to reduce the switching loss of the diode while reducing the turn-off loss of the IGBT by considering the diffusion length of holes and electrons in silicon, the width in the second direction X of the second region 112 can be set to be less than or about equal to the thickness in the first direction Z of the semiconductor part 10, which is, for example, a silicon layer. The thickness of the semiconductor part 10 is, for example, not less than 80 μm and not more than 120 μm.

On the other hand, when the width in the second direction X of the second region 112 is narrow, holes more easily reach the sixth semiconductor layer 16 (the n-type cathode layer) of the diode region 120 from the second region 112 in the diode operation. When holes are injected into the sixth semiconductor layer 16 (the n-type cathode layer), electrons are injected from the sixth semiconductor layer 16 (the n-type cathode layer) into the first semiconductor layer 11; and the switching loss of the diode is increased. Accordingly, the width in the second direction X of the second region 112 is, for example, not less than the distance in the second direction X between the insulating films 41 adjacent to each other in the second direction X (i.e., the width in the second direction X of the mesa positioned between mutually-adjacent third electrodes 30). For example, the width in the second direction X of the second region 112 can be about equal to the thickness in the first direction Z of the semiconductor part 10, which is a silicon layer. The thickness in the first direction Z of the semiconductor part 10 is greater than the width in the second direction X of the mesa.

Other embodiments will now be described; and mainly configurations that are different from those of the first embodiment above are described.

### Second Embodiment

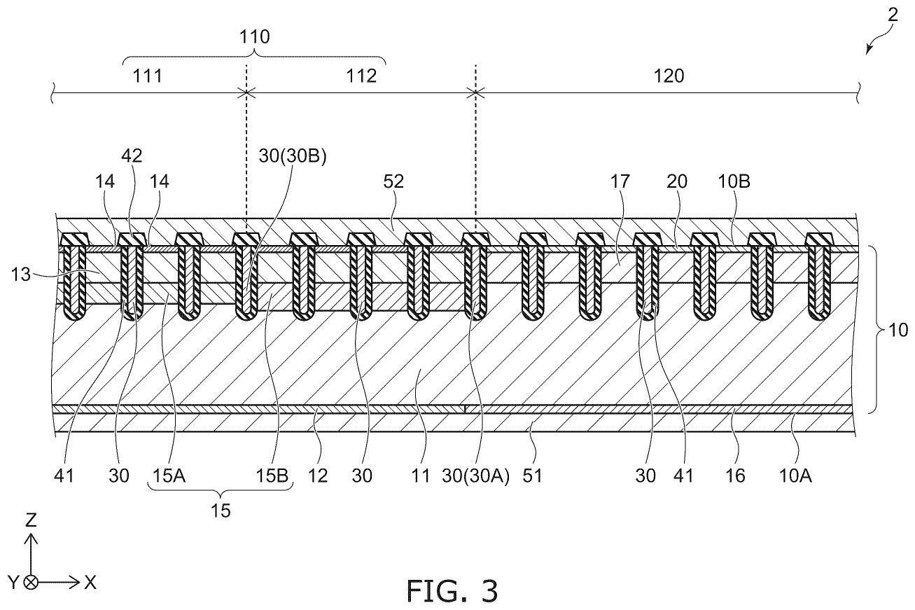

According to a semiconductor device 2 according to a second embodiment shown in FIG. 3, the thickness in the first direction Z of the second part 15B of the fifth semiconductor layer 15 positioned in the second region 112 is greater than the thickness in the first direction Z of the first part 15A of the fifth semiconductor layer 15 positioned in the first region 111. By setting the thickness of the second part 15B of the fifth semiconductor layer 15 positioned in at least a part of the second region 112 to be greater than the thickness of the first part 15A of the fifth semiconductor layer 15 positioned in the first region 111, the recovery loss (the switching loss) during reverse recovery of the diode operation can be reduced. In other words, it is unnecessary to compare the thickness of the second part 15B of the fifth semiconductor layer 15 positioned in the second region 112 and the thickness of the first part 15A of the fifth semiconductor layer 15 positioned in the first region 111 over the entire region. On the other hand, it is desirable for the thickness of the second part 15B of the fifth semiconductor layer 15 positioned in the second region 112 to be greater than the thickness of the first part 15A of the fifth semiconductor layer 15 positioned in the first region 111 over the entire surface of the second region 112. As a result, the switching loss of the diode operation can be further reduced.

With respect to the p-n junction between the third semiconductor layer 13 and the fifth semiconductor layer 15, the depth of the second part 15B is greater than the depth of the first part 15A. The n-type impurity concentration of the first part 15A and the n-type impurity concentration of the second part 15B are about the same.

According to the embodiment, in the fifth semiconductor layer 15 positioned in the transistor region 110, the thickness of the second part 15B positioned in the second region 112 proximate to the diode region 120 is set to be greater than the thickness of the first part 15A positioned in the first region 111 more distant to the diode region 120 than the second region 112. As a result, in the diode operation, fewer holes can be injected from the transistor region 110 into the first semiconductor layer 11 of the diode region 120; and the switching loss of the diode operation can be reduced.

It is favorable for the distance in the first direction Z between the first electrode 51 and the second part 15B of the fifth semiconductor layer 15 positioned in the second region 112 to be greater than the distance in the first direction Z between the first electrode 51 and the third electrode 30 positioned in the second region 112. In other words, the second part 15B that has a high n-type impurity concentration does not cover the corner of the lower end of the third electrode 30 at which the electric field is easily concentrated. As a result, the electric field that is applied to the first semiconductor layer 11 at the vicinity of the insulating film 41 can be relaxed, and the breakdown voltage can be increased. It is favorable for the distance in the first direction Z between the first electrode 51 and the second part 15B of the fifth semiconductor layer 15 positioned in the second region 112 to be greater than the distance in the first direction Z between the first electrode 51 and the lower end of the insulating film 41 positioned in the second region 112.

### Third Embodiment

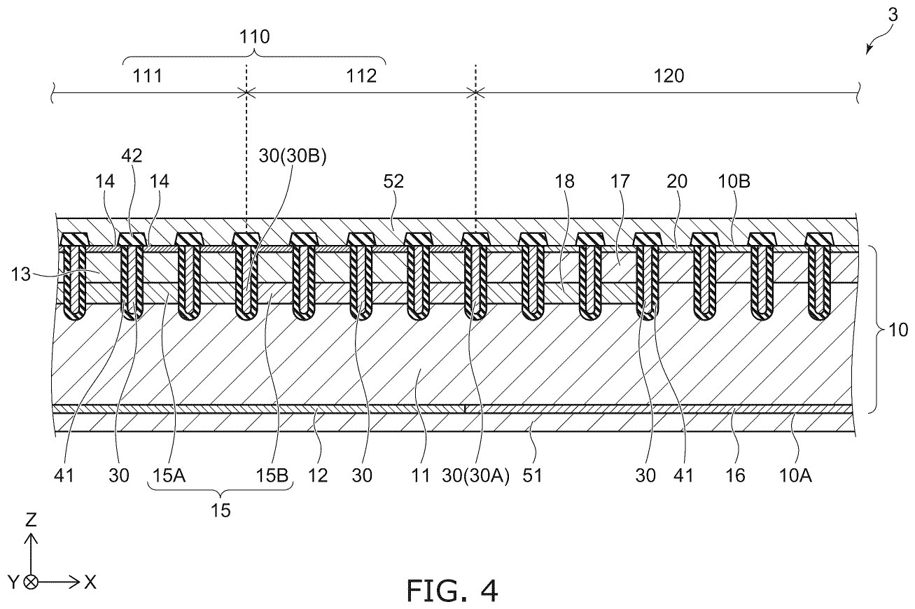

According to a semiconductor device 3 according to a third embodiment shown in FIG. 4, the semiconductor part 10 further includes an n-type eighth semiconductor layer 18.

The eighth semiconductor layer 18 is positioned in a partial region of the diode region 120 positioned at the transistor region 110 side between the first semiconductor layer 11 (the n-type base layer) and the seventh semiconductor layer 17 (the p-type anode layer). The n-type impurity concentration of the eighth semiconductor layer 18 is greater than the n-type impurity concentration of the first part 15A of the fifth semiconductor layer 15 positioned in the first region 111 of the transistor region 110. The n-type impurity concentration of the eighth semiconductor layer 18 is about equal to the n-type impurity concentration of the second part 15B of the fifth semiconductor layer 15 positioned in the second region 112 of the transistor region 110. As a result, fewer holes can be injected into the first semiconductor layer 11 of the diode region 120 in the diode operation; and the switching loss of the diode operation can be reduced.

The thickness (or the depth from the p-n junction with the seventh semiconductor layer 17) of the eighth semiconductor layer 18 is equal to the thickness (or the depth from the p-n junction with the third semiconductor layer 13) of the fifth semiconductor layer 15.

Two or more of the embodiments above may be appropriately combined within the extent of technical feasibility. For example, similarly to the first embodiment shown in FIG. 1, the n-type impurity concentration of the second part 15B of the fifth semiconductor layer 15 according to the second embodiment shown in FIG. 3 may be set to be greater than the n-type impurity concentration of the first part 15A. In other words, the second part 15B may be set to be thicker than the first part 15A; and the n-type impurity concentration of the second part 15B may be set to be greater than the n-type impurity concentration of the first part 15A.

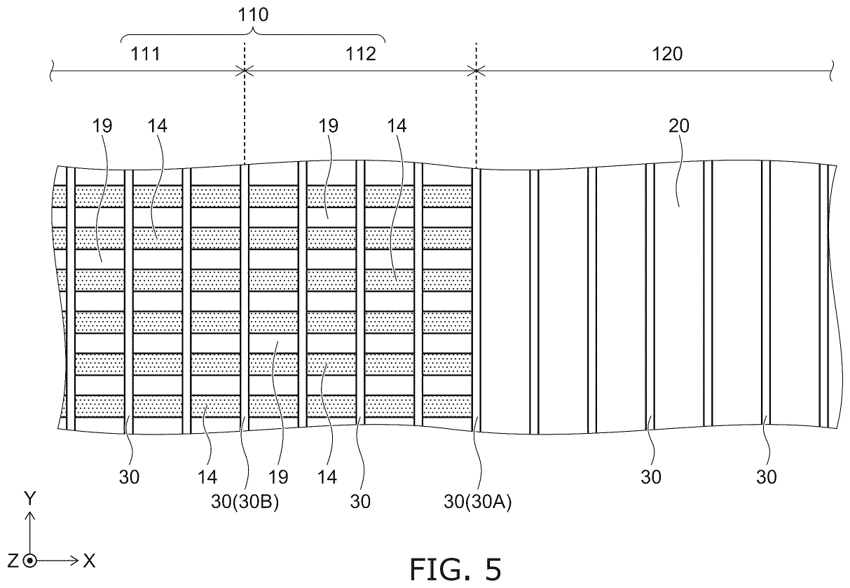

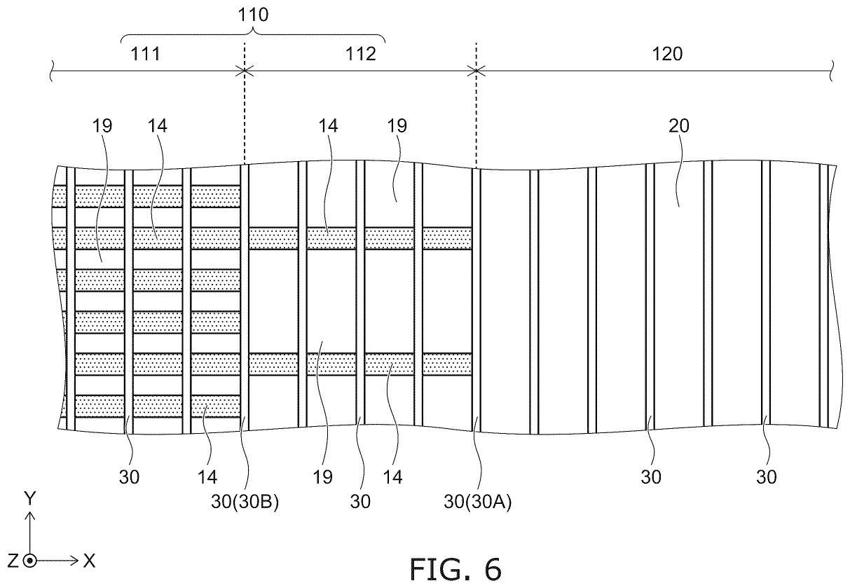

FIGS. 5 and 6 are schematic plan views showing arrangement examples of the third electrode 30 and the fourth semiconductor layer 14 (the n-type emitter layer) in the semiconductor devices of the embodiments above.

The semiconductor part 10 further includes a p-type ninth semiconductor layer 19. The ninth semiconductor layer 19 is formed in a portion of the front surface of the third semiconductor layer 13. The p-type impurity concentration of the ninth semiconductor layer 19 is greater than the p-type impurity concentration of the third semiconductor layer 13. The ninth semiconductor layer 19 contacts the second electrode 52. The third semiconductor layer 13 is electrically connected with the second electrode 52 via the ninth semiconductor layer 19.

As shown in FIG. 5, multiple fourth semiconductor layers 14 are arranged between the third electrodes 30 adjacent to each other in the second direction X in the transistor region 110. The fourth semiconductor layer 14 and the ninth semiconductor layer 19 are alternately arranged in the third direction Y. The fourth semiconductor layer 14 is not included in the diode region 120.

When viewed in plan, the ratio of the area of the fourth semiconductor layer 14 in the first region 111 to the area of the transistor region 110 may be different from the ratio of the area of the fourth semiconductor layer 14 in the second region 112 to the area of the transistor region 110.

In the example shown in FIG. 6, the ratio of the area of the fourth semiconductor layer 14 in the second region 112 to the area of the transistor region 110 is less than the ratio of the area of the fourth semiconductor layer 14 in the first region 111 to the area of the transistor region 110. The ratio of the area of the fourth semiconductor layer 14 in the second region 112 interposed between a pair of third electrodes 30 adjacent to each other in the second direction X to the area of the second region 112 interposed between the pair of third electrodes 30 adjacent to each other in the second direction X is less than the ratio of the area of the fourth semiconductor layer 14 in the first region 111 interposed between a pair of third electrodes 30 adjacent to each other in the second direction X to the area of the first region 111 interposed between the pair of third electrodes 30 adjacent to each other in the second direction X. In other words, the area proportion of the fourth semiconductor layer 14 in the second region 112 positioned between the pair of third electrodes 30 adjacent to each other in the second direction X is less than the area proportion of the fourth semiconductor layer 14 in the first region 111 positioned between the pair of third electrodes 30 adjacent to each other in the second direction X. As a result, the electrons injected into the second region 112 in the IGBT operation can be reduced. In the IGBT operation of the transistor region 110, there is a tendency for current to concentrate in the region (the second region 112) positioned at the boundary with the diode region 120. By reducing the electrons injected into the second region 112, the current concentration in the second region 112 can be relaxed, and the element breakdown can be suppressed.

The third electrode 30 that is not connected to a gate wiring part (a dummy electrode) may be included in the transistor region 110. For example, the dummy electrode is connected to the second electrode 52. The number of dummy electrodes in the first region 111 may be different from the number of dummy electrodes in the second region 112. For example, when the number of dummy electrodes in the second region 112 is greater than the number of dummy electrodes in the first region 111, the electrons injected into the second region 112 can be reduced, and the breakdown can be suppressed. For example, the ratio of the number of dummy electrodes in the first region 111 to the total number of the third electrodes 30 in the first region 111 may be different from the ratio of the number of dummy electrodes in the second region 112 to the total number of the third electrodes 30 in the second region 112. The ratio of the number of dummy electrodes in the first region 111 to the total number of the third electrodes 30 in the first region 111 is, for example, less than the ratio of the number of dummy electrodes in the second region 112 to the total number of the third electrodes 30 in the second region 112.

The fourth semiconductor layer 14 may not be included in the second region 112. All of the third electrodes 30 in the second region 112 may be dummy electrodes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode;
a semiconductor part positioned between the first electrode and the second electrode in a first direction, the semiconductor part including
a transistor region, and
a diode region adjacent to the transistor region in a direction crossing the first direction; and
a third electrode positioned in the semiconductor part,
the semiconductor part including
a first semiconductor layer positioned in the transistor region and the diode region, the first semiconductor layer being of a first conductivity type,
a second semiconductor layer positioned between the first electrode and the first semiconductor layer in the transistor region, the second semiconductor layer being of a second conductivity type,
a third semiconductor layer positioned between the first semiconductor layer and the second electrode in the transistor region, the third semiconductor layer being of the second conductivity type and being electrically connected with the second electrode,
a fourth semiconductor layer positioned between the third semiconductor layer and the second electrode in the transistor region, the fourth semiconductor layer being of the first conductivity type and being electrically connected with the second electrode,
a fifth semiconductor layer positioned between the first semiconductor layer and the third semiconductor layer in the transistor region, the fifth semiconductor layer being of the first conductivity type and having a higher first-conductivity-type impurity concentration than the first semiconductor layer,
a sixth semiconductor layer positioned between the first electrode and the first semiconductor layer in the diode region, the sixth semiconductor layer being of the first conductivity type and having a higher first-conductivity-type impurity concentration than the first semiconductor layer, and
a seventh semiconductor layer positioned between the first semiconductor layer and the second electrode in the diode region, the seventh semiconductor layer being of the second conductivity type and being electrically connected with the second electrode,
the transistor region including
a first region, and
a second region positioned between the first region and the diode region in the direction crossing the first direction,
a first-conductivity-type impurity concentration of the fifth semiconductor layer positioned in the second region being greater than a first-conductivity-type impurity concentration of the fifth semiconductor layer positioned in the first region.

2. The device according to claim 1, wherein
a thickness in the first direction of the fifth semiconductor layer positioned in the second region is greater than a thickness in the first direction of the fifth semiconductor layer positioned in the first region.

3. The device according to claim 1, wherein
a width of the second region in the direction crossing the first direction is less than a thickness in the first direction of the semiconductor part or about equal to the thickness in the first direction of the semiconductor part.

4. The device according to claim 1, wherein
the semiconductor part further includes an eighth semiconductor layer positioned between the first semiconductor layer and the seventh semiconductor layer in a partial region of the diode region, the partial region being positioned at the transistor region side of the diode region, the eighth semiconductor layer being of the first conductivity type, and
a first-conductivity-type impurity concentration of the eighth semiconductor layer is greater than the first-conductivity-type impurity concentration of the fifth semiconductor layer positioned in the first region.

5. The device according to claim 1, wherein
a ratio of an area of the fourth semiconductor layer in the first region to an area of the transistor region is different from a ratio of an area of the fourth semiconductor layer in the second region to an area of the transistor region.

6. The device according to claim 5, wherein
the ratio of the area of the fourth semiconductor layer in the second region to the area of the transistor region is less than the ratio of the area of the fourth semiconductor layer in the first region to the area of the transistor region.

7. The device according to claim 1, wherein
a plurality of the third electrodes are included, and
an area proportion of the fourth semiconductor layer in the second region positioned between a mutually-adjacent pair of third electrodes among the plurality of third electrodes in the second region is less than an area proportion of the fourth semiconductor layer in the first region positioned between a mutually-adjacent pair of third electrodes among the plurality of third electrodes in the first region.

8. The device according to claim 1, wherein
a plurality of the third electrodes are included,
the plurality of third electrodes include at least one dummy electrode electrically connected with the second electrode, and
a number of the at least one dummy electrode in the first region is different from a number of the at least one dummy electrode in the second region.

9. A semiconductor device, comprising:
a first electrode;
a second electrode;
a semiconductor part positioned between the first electrode and the second electrode in a first direction, the semiconductor part including
a transistor region, and
a diode region adjacent to the transistor region in a direction crossing the first direction; and
a third electrode positioned in the semiconductor part,
the semiconductor part including
a first semiconductor layer positioned in the transistor region and the diode region, the first semiconductor layer being of a first conductivity type,
a second semiconductor layer positioned between the first electrode and the first semiconductor layer in the transistor region, the second semiconductor layer being of a second conductivity type,
a third semiconductor layer positioned between the first semiconductor layer and the second electrode in the transistor region, the third semiconductor layer being of the second conductivity type and being electrically connected with the second electrode,
a fourth semiconductor layer positioned between the third semiconductor layer and the second electrode in the transistor region, the fourth semiconductor layer being of the first conductivity type and being electrically connected with the second electrode,
a fifth semiconductor layer positioned between the first semiconductor layer and the third semiconductor layer in the transistor region, the fifth semiconductor layer being of the first conductivity type and having a higher first-conductivity-type impurity concentration than the first semiconductor layer,
a sixth semiconductor layer positioned between the first electrode and the first semiconductor layer in the diode region, the sixth semiconductor layer being of the first conductivity type and having a higher first-conductivity-type impurity concentration than the first semiconductor layer, and
a seventh semiconductor layer positioned between the first semiconductor layer and the second electrode in the diode region, the seventh semiconductor layer being of the second conductivity type and being electrically connected with the second electrode,
the transistor region including
a first region, and
a second region positioned between the first region and the diode region in the direction crossing the first direction,
a thickness in the first direction of the fifth semiconductor layer positioned in the second region being greater than a thickness in the first direction of the fifth semiconductor layer positioned in the first region.

10. The device according to claim 9, further comprising:
an insulating film located between the third electrode and the semiconductor part,
a distance in the first direction between the first electrode and the fifth semiconductor layer positioned in the second region being greater than a distance in the first direction between the first electrode and a lower end of the insulating film positioned in the second region.

11. The device according to claim 9, wherein
a ratio of an area of the fourth semiconductor layer in the first region to an area of the transistor region is different from a ratio of an area of the fourth semiconductor layer in the second region to an area of the transistor region.

12. The device according to claim 11, wherein
the ratio of the area of the fourth semiconductor layer in the second region to the area of the transistor region is less than the ratio of the area of the fourth semiconductor layer in the first region to the area of the transistor region.

13. The device according to claim 9, wherein
a plurality of the third electrodes are included, and
an area proportion of the fourth semiconductor layer in the second region positioned between a mutually-adjacent pair of third electrodes among the plurality of third electrodes in the second region is less than an area proportion of the fourth semiconductor layer in the first region positioned between a mutually-adjacent pair of third electrodes among the plurality of third electrodes in the first region.

14. The device according to claim 9, wherein
a plurality of the third electrodes are included,
the plurality of third electrodes include at least one dummy electrode electrically connected with the second electrode, and
a number of the at least one dummy electrode in the first region is different from a number of the at least one dummy electrode in the second region.
